(19) United States
(12) Patent Application Publication
(10) Pub. No.: US 2017/0197378 A1
(43) Pub. Date: Jul. 13, 2017

(54) COMPOSITE SHEET AND MANUFACTURING METHOD THEREFOR

(71) Applicant: Panasonic Intellectual Property Management Co., Ltd., Osaka (JP)

(72) Inventors: YUUICHI ABE, Hokkaido (JP); TAKESHI FUJII, Osaka (JP)

(21) Appl. No.: 15/324,385

(22) PCT Filed: Nov. 5, 2015
(86) PCT No.: PCT/JP2015/005547

§ 371 Date: Jan. 6, 2017

(30) Foreign Application Priority Data
Nov. 6, 2014 (JP) 2014-225744

(51) Int. Cl. B32B 5/02; H01L 23/373; H05K 7/20; B32B 37/06

(52) U.S. Cl. CPC B32B 5/022; B32B 37/06; H01L 23/3733; H05K 7/20481; B32B 2307/206; B32B 2307/304; B32B 2262/00

(57) ABSTRACT

A composite sheet includes heat-insulating sheet (13) including a fiber sheet (11) made of fibers and a xerogel (12) held between the fibers, and a first electrical-insulation film (14) disposed on surface (31) of heat-insulating sheet (13). Fiber sheet (11) is fusion-bonded to surface (31) of first electrical-insulation film (14).

### TECHNICAL FIELD

The present disclosure relates to a composite sheet for use as a heat-insulating device of various electronic apparatuses, and to a method of manufacturing the sheet.

### BACKGROUND ART

In recent years, rapid progress in various functions and processing abilities of electronic apparatuses has brought about a tendency for their electronic components, most notably semiconductor devices, to generate increased amounts of heat. Such an increased heat generation from the electronic components poses problems that, for example, the shell of a smartphone is partially heated to high temperatures, leading to possible uncomfortable feeling of a user of the phone.

A solution to the above problem attributed to the heat generation of such electronic components includes mainly diffusing the generated heat with a heat-conducting sheet, and mainly insulating the generated heat with a heat-insulating sheet.

Such a heat-insulating sheet includes a silica xerogel held in a sheet made of a fiber aggregate.

A technology associated with the above heat-insulating sheet is disclosed in PTL 1.

### CITATION LIST

### Patent Literature

PTL 1: Japanese Patent Laid-Open Publication No. 2011-136859

### SUMMARY

A composite sheet according to the present disclosure includes a heat-insulating sheet which includes a fiber sheet made of fibers and a xerogel held between the fibers. The composite sheet further includes a first electrical-insulation film disposed on a first surface of the heat-insulating sheet. The fiber sheet is fusion-bonded to the first surface of the first electrical-insulation film.

### BRIEF DESCRIPTION OF DRAWINGS

FIG. 1A is a cross-sectional view of a composite sheet according to Exemplary Embodiment 1.

FIG. 1B is an enlarged view of the composite sheet according to

Embodiment 1.

FIG. 2 is a cross-sectional view of another composite sheet according to Embodiment 1.

FIG. 3 is a cross-sectional view of a modified example of a composite sheet according to Embodiment 1.

FIG. 4A illustrates a method of manufacturing the composite sheet.

FIG. 4B illustrates the method of manufacturing the composite sheet.

FIG. 4C illustrates the method of manufacturing the composite sheet.

### DETAIL DESCRIPTION OF PREFERRED EMBODIMENTS

A heat-insulating sheet disclosed in Patent Literature 1 uses a silica xerogel that exhibits low bonding strength among particles of the silica xerogel. When another member is bonded to the silica xerogel with an adhesive, the member may be peeled from between the particles of the silica xerogel.

Hereinafter, descriptions will be made regarding a heat-insulating sheet which can solve the problems described above, with reference to the accompanying drawings. It is noted, however, that each of exemplary embodiments described below is nothing more than a specific example. Numerical values, shapes, materials, constituent elements, arrangements and connections of the constituent elements, steps, processing orders of the steps, etc. shown in the following exemplary embodiments are mere examples, and therefore are not intended to limit the present invention. Moreover, of the constituent elements in the following exemplary embodiments, constituent elements not recited in any one of the independent claims which define the most generic concept are described as optional constituent elements. Note that, hereinafter, the same or functionally equivalent elements are designated by the same numerals and symbols throughout the figures, and their duplicate explanations are omitted.

### Exemplary Embodiment 1

### 1. Configuration of Composite Sheet

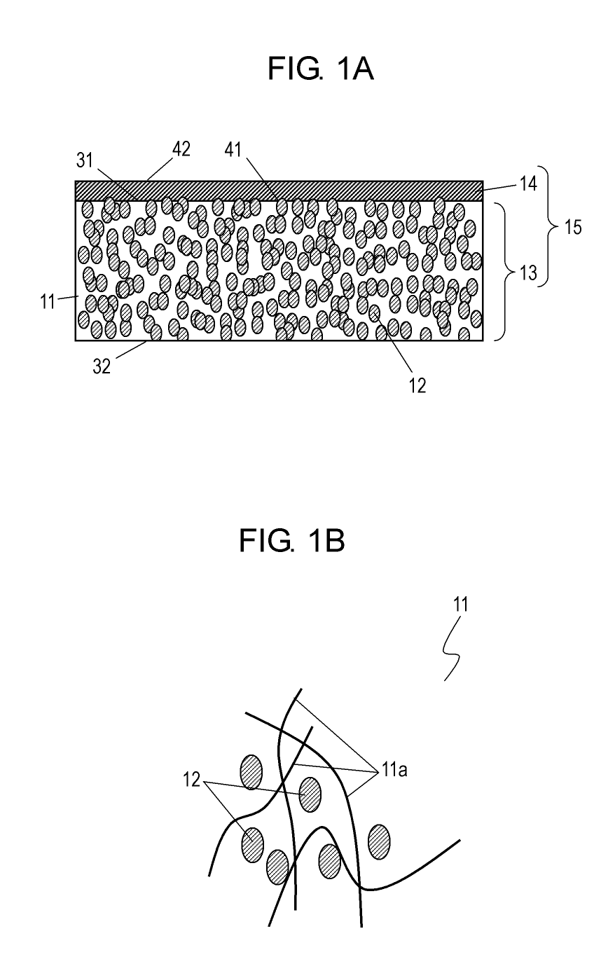

FIG. 1A is a cross-sectional view of composite sheet 15 according to Exemplary Embodiment 1. FIG. 1B is an enlarged view of composite sheet 15 according to Embodiment 1.

As shown in FIG. 1A, composite sheet 15 includes heat-insulating sheet 13 that has surfaces 31 and 32 on mutually opposite sides, and electrical-insulation film 14 that has surface 41. The thickness of heat-insulating sheet 13 is approximately 0.5 mm, for example. The thickness of electrical-insulation film 14 is approximately 0.03 mm, for example.

As shown in FIG. 1B, heat-insulating sheet 13 includes fiber sheet 11 made of fibers 11a, and silica xerogel 12 held between fibers 11a of fiber sheet 11. Fiber sheet 11 is a nonwoven fabric made of fibers 11a made of thermoplastic resin of polyethylene terephthalate (referred to as “PET,” hereinafter).

Silica xerogel 12 is an aggregate of silica particles. The size of each silica particle is about several nanometers. Silica xerogel 12 has fine pores between the silica particles. The size of each pore is so small that no convection of air occurs through the pore. This results in a very small amount of gas-phase thermal conduction. Moreover, about 90% of the volume of silica xerogel 12 is occupied with air, resulting in a very small amount of solid-phase thermal conduction. For this reason, the thermal conductivity of sheet 13 is so small, i.e. ranging from about 0.018 to about 0.024 W/m•K, that the sheet is useful as a heat-insulating material.

Composite sheet 15 includes electrical-insulation film 14 and fiber sheet 11 bonded to electrical-insulation film 14. This bonding is made by thermal fusion-bonding such that surface 41 of the electrical-insulation film is bonded to portions of fibers 11a of the fiber sheet of heat-insulating sheet 13 exposed on surface 31 of heat-insulating sheet 13. Electrical-insulation film 14 and fiber sheet 11 are bonded by thermal fusion-bonding into a one-piece body, providing strong bonding between electrical-insulation film 14 and fiber sheet 11. Temperature characteristics, such as a melting temperature and a curing temperature, of the material configuring fiber sheet 11 are preferably close to those of the material of electrical-insulation film 14. The closer the temperature characteristics of the materials of fiber sheet 11 and electrical-insulation film 14 are, the more easily the thermal fusion-bonding between fiber sheet 11 and electrical-insulation film 14 can be carried out, providing a strong bonding. For this reason, both fiber sheet 11 and electrical-insulation film 14 are preferably made of the same material.

The thickness of a portion at which fiber sheet 11 and electrical-insulation film 14 are fusion-bonded to each other by thermal fusion-bonding is, e.g. about 20 μm. The portion at which fiber sheet 11 and electrical-insulation film 14 are bonded is a portion that is formed by once fusing a part of fiber sheet 11 together with a part of electrical-insulation film 14 and then solidifying the parts.

The thickness of the portion at which fiber sheet 11 and electrical-insulation film 14 are fusion-bonded to each other by thermal fusion-bonding is preferably not larger than an average diameter of fibers 11a of fiber sheet 11. The thickness of the portion not larger than the average diameter of fiber sheet 11 provides a strong bonding between fiber sheet 11 and electrical-insulation film 14 while the portion formed by fusion bonding electrical-insulation film 14 to fiber sheet 11 by thermal fusion-bonding. This configuration prevents interstices between fiber sheet 11 and electrical-insulation film 14, decreasing degradation of the heat insulation performance. Moreover, the average diameter of fibers 11a of fiber sheet 11 is preferably equal to or larger than 20 μm and is equal to or smaller than 30 μm. The average diameter of fibers 11a of fiber sheet 11 not smaller than 20 μm and not larger than 30 μm provides a strong bonding of electrical-insulation film 14 to fiber sheet 11.

The material of fiber sheet 11 may include a polyester fiber, polyimide fiber, or aramid fiber, other than the PET fiber.

A configuration in which graphite sheet 16 is bonded to composite sheet 15 will be described below.

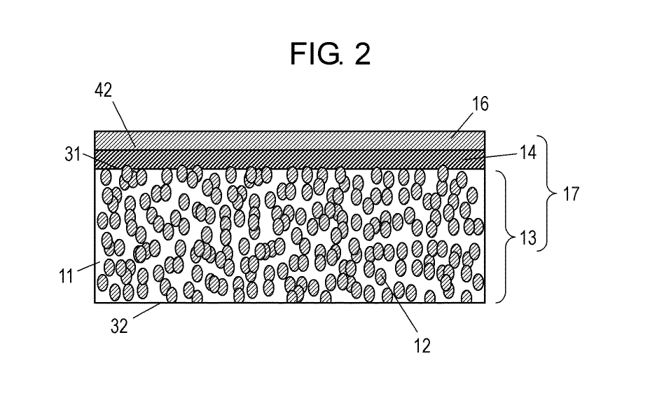

FIG. 2 is a cross-sectional view of composite sheet 17 according to the embodiment. As shown in FIG. 2, composite sheet 17 includes graphite sheet 16 bonded to surface 42 of electrical-insulation film 14 opposite to surface 41 of electrical-insulation film 14. If graphite sheet 16 is bonded directly to heat-insulating sheet 13 with an adhesive, for example, the sheet may be peeled from particles of the silica xerogel of the heat-insulating sheet since the silica xerogel is exposed from surface 32 of the heat-insulating sheet. For this reason, graphite sheet 16 is bonded to surface 42 of electrical-insulation film 14. Graphite sheet 16 is preferably formed by thermally decomposing a polyimide film. Graphite sheet 16 formed by thermally decomposing the polyimide film has a thermal conductivity in a surface direction not smaller than 700 W/m•K.

Graphite sheet 16 bonded to heat-insulating sheet 13 allows composite sheet 17 to exhibit both the high heat insulation performance and the high heat conduction performance. Graphite sheet 16 prevents the occurrence of a heat spot caused by local heating in the shell of an electronic apparatus.

### 2. Method of Manufacturing Composite Sheet

A method of manufacturing composite sheet 15 according to Embodiment 1 will be described below with reference to the drawings.

FIGS. 4A to 4C illustrate the method of manufacturing composite sheet 15.

In the method of manufacturing composite sheet 15, fiber sheet 11 having a thickness of about 0.5 mm is thermally fusion-bonded to electrical-insulation film 14 having a thickness of about 0.03 mm, thereby providing substrate 21. The thickness of a portion at which fiber sheet 11 is thermally fusion bonded to electrical-insulation film 14 is about 20 μm. Fiber sheet 11 can be thermally fusion-bonded to electrical-insulation film 14 by pressing a hot-iron on electrical-insulation film 14 or by irradiation with infrared light. The material of both fiber sheet 11 and electrical-insulation film 14 is a thermoplastic resin of PET. Fiber sheet 11 is a nonwoven fabric made of the PET. The thickness of fiber sheet 11 is preferably not smaller than 0.03 mm and not larger than 2.0 mm. This thickness of fiber sheet 11 not smaller than 0.03 mm and not larger than 2.0 mm allows composite sheet 15 to exhibit the advantages according to the present disclosure.

Next, as shown in FIG. 4B, substrate 21 is immersed in material solution 20 of the silica xerogel, thereby impregnating fibers 11a of fiber sheet 11 with material solution 20 of the silica xerogel. Material solution 20 of the silica xerogel is, e.g. a sol solution made of a starting material of water glass or a solution of sodium silicate in water. The solvent of the sol solution is water or alcohol. A catalyst may be added to the sol solution, if necessary.

Then, the sol solution is held at a predetermined temperature for a predetermined period of time to be gel while substrate 21 is immersed in the sol solution.

Next, a silylation agent is added to the resulting gel solution, thereby substituting silicon for active hydrogen of groups of organic compounds contained in the gel solution, with the groups including: a hydroxyl group, amino group, carboxyl group, amide group, and mercapto group.

Then, the gel solution including the active hydrogen substituted with silicon is held at a predetermined temperature for a predetermined period of time, thereby causing the solvent to volatilize. This provides composite sheet 15 in which the silica xerogel is held between fibers 11a, as shown in FIG. 4C.

Next, a method of manufacturing composite sheet 17 shown in FIG. 2 will be described.

Substrate 21 is immersed in material solution 20 of the silica xerogel to cause silica xerogel 12 to adhere to surface 42 of electrical-insulation film 14. Silica xerogel 12 adhering to surface 42 can be easily removed. After silica xerogel 12 adhering to surface 42 is removed, graphite sheet 16 is bonded to surface 42.

Silica xerogel 12 is exposed from surface 32 of heat-insulating sheet 13. If graphite sheet 16 is bonded to the surface, the graphite sheet can be peeled off from the silica particles.

Electrical-insulation film 14 may be boded to fiber sheet 11 by a method, other than the thermal fusion-bonding, e.g., with a double-sided adhesive tape or an adhesive. An acid solution, such as hydrochloric acid, which is used in preparing the silica xerogel can unfavorably deteriorate the double-sided adhesive tape or the adhesive, decreasing adhesive strength.

The surface roughness of surface 41 of electrical-insulation film 14 is preferably larger than that of surface 42 of electrical-insulation film 14. The surface roughness of surface 41 is larger than that of surface 42, thereby providing a large amount of the silica xerogel on surface 41. As a result, composite sheet 15 is improved in heat insulation performance and also allows the graphite sheet to be easily bonded to surface 42.

### MODIFIED EXAMPLE OF FIRST EXEMPLARY EMBODIMENT

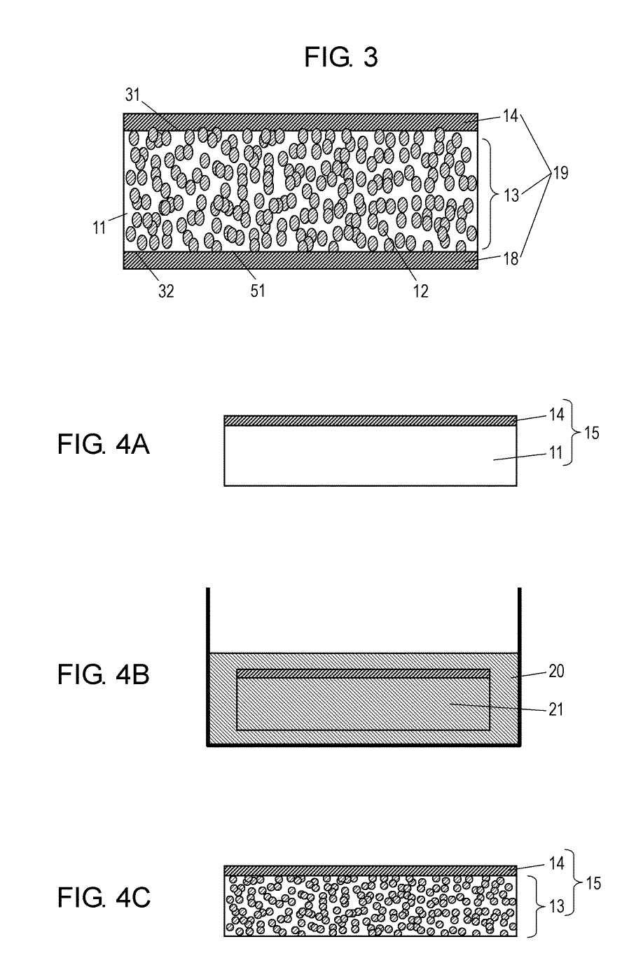

FIG. 3 is a cross-sectional view of composite sheet 19 of a modified example according to Embodiment 1.

The same configurations as composite sheet 15 according to Embodiment 1 will not be described. In composite sheet 19 according to the embodiment, surface 51 of electrical-insulation film 18 is thermally fusion-bonded to fibers 11a of fiber sheet 11 while the fibers are exposed from surface 32. Electrical-insulation film 18 and fiber sheet 11 are bonded by thermal fusion-bonding into a one-piece body, providing strong bonding between electrical-insulation film 18 and fiber sheet 11.

Electrical-insulation film 14 and electrical-insulation film 18 disposed on surface 31 and surface 32 at both sides of heat-insulating sheet 13, respectively, protect the heat-insulating sheet from external impacts.

As described above, according to the embodiment, the electrical-insulation film is fusion-bonded to the fiber sheet, so that the electrical-insulation film can hardly be peeled off from the fiber sheet, providing the composite sheet with the high heat insulation performance.

### INDUSTRIAL APPLICABILITY

A composite sheet according to the present disclosure includes the silica xerogel having a high heat insulation performance and is formed by fusion-bonding the electrical-insulation film to the fiber sheet, hence preventing the electrical-insulation film from being peeled off from the fiber sheet. The composite sheet is highly useful in industrial applications.

### REFERENCE MARKS IN THE DRAWINGS

11 fiber sheet

12 silica xerogel

13 heat-insulating sheet

14 electrical-insulation film

15 composite sheet

16 graphite sheet

17 composite sheet

18 electrical-insulation film

19 composite sheet

20 material solution of silica xerogel

21 substrate

31 surface

32 surface

41 surface

42 surface

51 surface

1. A composite sheet comprising:
a heat-insulating sheet having a first surface and a second surface opposite to the first surface, the heat-insulating sheet including
a fiber sheet made of fibers and
a xerogel held between the fibers; and
a first electrical-insulation film having a first surface fusion-bonded to the first surface of the heat-insulating sheet.

2. The composite sheet according to claim 1, wherein the fibers are made of thermoplastic resin, and the fiber sheet is a nonwoven fabric.

3. The composite sheet according to claim 1,
wherein a thickness of a portion at which the first electrical-insulation film is fusion-bonded to the fiber sheet at the first surface of the first electrical-insulation film and the first surface of the heat-insulating sheet is equal to or smaller than an average diameter of the fibers.

4. The composite sheet according to claim 1, wherein a material configuring the fiber sheet is identical to a material of the first electrical-insulation film.

5. The composite sheet according to claim 1, further comprising a graphite sheet disposed on a second surface of the first electrical-insulation film opposite to the first surface of the first electrical-insulation film.

6. The composite sheet according to claim 1, further comprising a second electrical-insulation film fusion-bonded to the second surface of the heat-insulating sheet.

7. A method of manufacturing a composite sheet, the method comprising:
forming a substrate by fusion-bonding an electrical-insulation film to a surface of a fiber sheet made of fibers; and
impregnating at least the fibers of the fiber sheet of the substrate with a material solution of a xerogel.

8. The method according to claim 7, wherein said forming the substrate comprises fusion-bonding the electrical-insulation film to the fiber sheet by heating at least one of the electrical-insulation film and the fiber sheet.

9. The method according to claim 7, wherein the fibers are made of thermoplastic resin, and the fiber sheet is a nonwoven fabric.

10. The method according to claim 7, wherein said impregnating at least the fibers of the fiber sheet of the substrate with the material solution of the xerogel comprises immersing at least the fiber sheet of the substrate in the material solution.

11. The method according to claim 7, wherein said impregnating at least the fibers of the fiber sheet of the substrate with the material solution of the xerogel comprises applying the material solution to at least the fiber sheet of the substrate.
